(19) United States
(12) Patent Application Publication
(10) Pub. No.: US 2025/0301676 A1
(43) Pub. Date: Sep. 25, 2025

(54) CAPACITOR AND METHOD OF MANUFACTURING CAPACITOR

(71) Applicant: KABUSHIKI KAISHA TOSHIBA, Tokyo (JP)

(72) Inventors: Hiroki KAWAKAMI, Yokohama (JP); Susumu OBATA, Yokohama (JP); Kazuhito HIGUCHI, Yokohama (JP); Takayuki TAJIMA, Sagamihara (JP)

(73) Assignee: KABUSHIKI KAISHA TOSHIBA, Tokyo (JP)

(21) Appl. No.: 19/058,698

(22) Filed: Feb. 20, 2025

(30) Foreign Application Priority Data
Mar. 22, 2024 (JP) 2024-046788

(51) Int. Cl. H10D 1/68; H10D 1/00

(52) U.S. Cl. CPC H10D 1/716; H10D 1/043

(57) ABSTRACT

According to one embodiment, a method of manufacturing a capacitor includes providing a substrate to be processed; providing a first conductive material portion on a main surface of a semiconductor substrate located in an opening; processing the conductive layer in a pattern shape by dry etching; providing a first contact electrode, a second contact electrode, and a second conductive material portion; performing dry etching to the first conductive material portion to disconnect electrical connection between a connection portion and the semiconductor substrate; and performing wet etching to the second conductive material portion to disconnect electrical connection between the first contact electrode and the second contact electrode.

### CROSS-REFERENCE TO RELATED APPLICATION

This application is based upon and claims the benefit of priority from Japanese Patent Application No. 2024-046788, filed Mar. 22, 2024, the entire contents of which are incorporated herein by reference.

### FIELD

Embodiments of the present invention relate to a capacitor and a method of manufacturing a capacitor.

### BACKGROUND

In a process of producing a Si capacitor, after formation of a trench in a Si substrate, a dielectric film and a poly-Si film are formed, and then a poly-Si film is patterned. The poly-Si film can be patterned by, for example, chemical dry etching (CDE). The CDE is performed in a state where the Si substrate as a processing-target substrate is clamped by an electrostatic chuck. In a case where the poly-Si film is patterned, contact between the poly-Si film and the Si substrate is lost. As a result, electric charges remain in the poly-Si film. Thus, the Si substrate is not separated from a stage even upon dechucking, and damage such as cracks occurs in the Si substrate in a case where the Si substrate is pushed up from the stage by a conductive lift pin.

### BRIEF DESCRIPTION OF DRAWINGS

FIG. 1 is a top view of a processing-target substrate to which a first step of a method of an embodiment is applied.

FIG. 2 is a cross-sectional view of the processing-target substrate illustrated in FIG. 1 taken along line II-II.

FIG. 3 is a schematic circuit diagram illustrating a connection state of a portion to be a first fuse portion (poly-Si fuse portion).

FIG. 4 is a top view of a processing-target substrate to which a second step of the method of the embodiment is applied.

FIG. 5 is a cross-sectional view of the processing-target substrate illustrated in FIG. 4 taken along line V-V.

FIG. 6 is a top view of a processing-target substrate to which a third step of the method of the embodiment is applied.

FIG. 7 is a cross-sectional view of the processing-target substrate illustrated in FIG. 6 taken along line VII-VII.

FIG. 8 is a schematic circuit diagram illustrating a connection state of the first fuse portion (poly-Si fuse portion).

FIG. 9 is a top view of a processing-target substrate to which a fourth step of the method of the embodiment is applied.

FIG. 10 is a cross-sectional view of the processing-target substrate illustrated in FIG. 9 taken along line X-X.

FIG. 11 is a top view of a processing-target substrate to which a fifth step of the method of the embodiment is applied.

FIG. 12 is a cross-sectional view of the processing-target substrate illustrated in FIG. 11 taken along line XII-XII.

FIG. 13 is a top view of a processing-target substrate to which a sixth step of the method of the embodiment is applied.

FIG. 14 is a cross-sectional view of the processing-target substrate illustrated in FIG. 13 taken along line XIV-XIV.

FIG. 15 is a schematic circuit diagram illustrating a connection state of the first fuse portion (poly-Si fuse portion) and a second fuse portion (Al fuse portion).

FIG. 16 is a top view of a processing-target substrate to which a seventh step of the method of the embodiment is applied.

FIG. 17 is a cross-sectional view of the processing-target substrate illustrated in FIG. 16 taken along line XVII-XVII.

FIG. 18 is a top view of a processing-target substrate to which an eighth step of the method of the embodiment is applied.

FIG. 19 is a cross-sectional view of the processing-target substrate illustrated in FIG. 18 taken along line XIX-XIX.

FIG. 20 is a schematic circuit diagram illustrating a connection state of the first fuse portion (poly-Si fuse portion) and the second fuse portion (Al fuse portion).

FIG. 21 is a top view of a processing-target substrate to which a ninth step of the method of the embodiment is applied.

FIG. 22 is a cross-sectional view of the processing-target substrate illustrated in FIG. 21 taken along line XXII-XXII.

FIG. 23 is a schematic circuit diagram illustrating a connection state of the second fuse portion (Al fuse portion) and a third fuse portion (Al fuse portion).

FIG. 24 is a top view of a processing-target substrate to which a tenth step of the method of the embodiment is applied.

FIG. 25 is a cross-sectional view of the processing-target substrate illustrated in FIG. 24 taken along line XXV-XXV.

FIG. 26 is a schematic circuit diagram illustrating a connection state of the second fuse portion (Al fuse portion) and the third fuse portion (Al fuse portion).

FIG. 27 is a cross-sectional view of a processing-target substrate to which an eleventh step of the method of the embodiment is applied taken along an x-axis direction.

FIG. 28 is a top view illustrating a capacitor manufactured by the method of the embodiment.

FIG. 29 is a cross-sectional view of the capacitor illustrated in FIG. 28 taken along line XXVIIII-XXVIIII.

FIG. 30 is a schematic view illustrating a step of attaching a processing-target substrate to which dry etching is applied to a stage of an electrostatic chuck.

FIG. 31 is a schematic view illustrating a state of the processing-target substrate attached to the stage of the electrostatic chuck.

FIG. 32 is a schematic view illustrating a state in which the processing-target substrate is clamped on the stage of the electrostatic chuck.

FIG. 33 is a schematic view illustrating a state after dry etching of the processing-target substrate attached to the stage of the electrostatic chuck.

FIG. 34 is a schematic view illustrating a state of the processing-target substrate in a case where the processing-target substrate illustrated in FIG. 33 is dechucked from the stage of the electrostatic chuck.

FIG. 35 is a schematic view illustrating a state in which damage occurs in the processing-target substrate in a case where the processing-target substrate is dechucked from the stage of the electrostatic chuck.

### DETAILED DESCRIPTION

According to one embodiment, a method of manufacturing a capacitor is provided. The method including:
providing a substrate to be processed, the substrate including: a semiconductor substrate including a main surface having one or more recesses; a conductive layer provided on the main surface and in the one or more recesses of the semiconductor substrate; and a dielectric layer provided between the conductive layer and the semiconductor substrate, an opening penetrating the dielectric layer and the conductive layer that are located on the main surface of the semiconductor substrate;
providing a first conductive material portion on the main surface of the semiconductor substrate located in the opening;
processing the conductive layer in a pattern shape by dry etching, and the pattern shape including a connection portion extending from the conductive layer and connected to the opening;
providing a first contact electrode electrically connected to the conductive layer, a second contact electrode electrically connected to the semiconductor substrate, and a second conductive material portion electrically connecting the first contact electrode and the second contact electrode;
performing dry etching to the first conductive material portion to disconnect electrical connection between the connection portion and the semiconductor substrate; and performing wet etching to the second conductive material portion to disconnect electrical connection between the first contact electrode and the second contact electrode.

According to another embodiment, a capacitor including:
a semiconductor substrate including a main surface having one or more recesses;
a conductive layer provided in the one or more recesses and on the main surface of the semiconductor substrate;
a dielectric layer disposed between the conductive layer and the semiconductor substrate;
a connection portion from which the conductive layer located on the main surface of the semiconductor substrate extends;
an opening connected to the connection portion and including a bottom wall located in the main surface of the semiconductor substrate;
a first contact electrode electrically connected to the conductive layer;
a second contact electrode electrically connected to the semiconductor substrate;
a hole located between the first contact electrode and the second contact electrode and including a bottom wall located in the main surface of the semiconductor substrate; and
an insulating layer provided in the opening and the hole.

Hereinafter, embodiments will be described in detail with reference to the accompanying drawings. Constituents which achieve the same or similar functions are denoted by the same reference numerals throughout the drawings, and repetitive descriptions will be omitted.

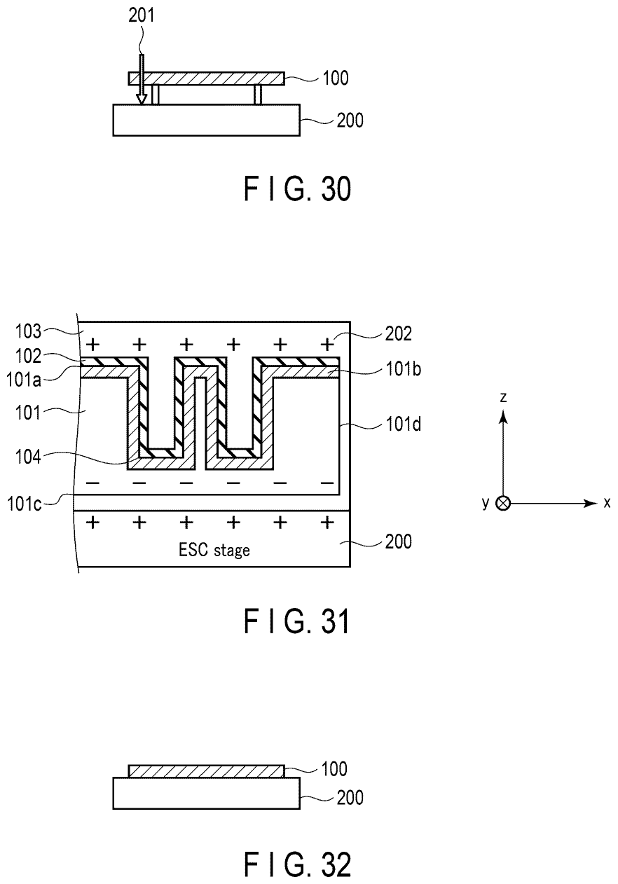

Dry etching is performed in a state where the substrate to be processed as the processing-target substrate is clamped on a stage of an electrostatic chuck (ESC) in a reaction chamber. The electrostatic chuck used in the dry etching process will be described with reference to FIGS. 30 to 35. The substrate to be processed may be named the processing-target substrate.

FIG. 30 is a schematic view illustrating a step of attaching a processing-target substrate to which dry etching is applied to a stage of an electrostatic chuck. First, a processing-target substrate 100 before application of the dry etching is pressed against a stage 200 of an electrostatic chuck by a conductive lift pin 201.

As illustrated in FIG. 31, the processing-target substrate 100 includes a semiconductor substrate 101, a dielectric layer 102, and a conductive layer 103. The semiconductor substrate 101 is a Si wafer having a doped layer 101b doped with impurities on one main surface 101a. A plurality of recesses (trenches) 104 are provided in one main surface 101a of the semiconductor substrate 101. A depth direction of each recess (trench) 104 is along a z-axis direction. In addition, the recesses (trenches) 104 are arranged along an x-axis direction at intervals from each other. Each recess (trench) 104 extends along a y-axis direction.

The dielectric layer 102 is provided on the main surface 101a of the semiconductor substrate 101 and an inner surface of each recess 104. The conductive layer 103 is embedded in each recess 104. The conductive layer 103 covers the dielectric layer 102 in the recess 104 and the dielectric layer 102 located on the main surface 101a of the semiconductor substrate 101. In addition, the conductive layer 103 covers a main surface 101c on the opposite side and an end surface 101d connecting the two main surfaces 101a and 101c. The conductive layer 103 is formed of, for example, poly-Si doped with impurities. Therefore, as illustrated in FIG. 30, upon contact of the conductive lift pin 201 of the electrostatic chuck with the processing-target substrate 100, charges 202 from the electrostatic chuck can be stored in the conductive layer 103. As a result, as illustrated in FIG. 32, the semiconductor substrate 101 of the processing-target substrate 100 is electrostatically attracted to the stage 200 of the electrostatic chuck. As a result, the conductive layer 103 is electrically conducted with the stage 200 of the electrostatic chuck. In this state, in a case where the processing-target substrate 100 is detached from the electrostatic chuck by pushing up the processing-target substrate by the conductive lift pin 201, the residual charges 202 in the conductive layer 103 can be discharged from the conductive layer 103 to the stage.

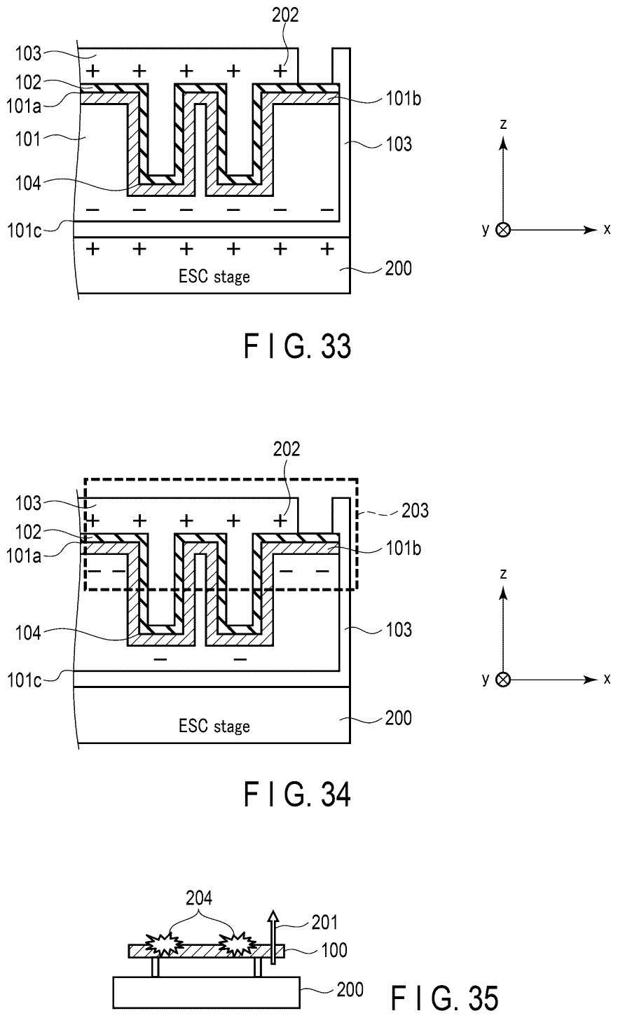

However, patterning of the conductive layer 103 by dry etching disconnects electrical conduction between the conductive layer 103 and the stage 200 of the electrostatic chuck as illustrated in FIG. 33. As a result, as illustrated in FIG. 34, the residual charges 202 remain in the conductive layer 103. A region 203 in which the residual charges 202 remain is indicated by a dotted frame. Therefore, as illustrated in FIG. 35, even pushing up of the processing-target substrate 100 by the conductive lift pin 201 cannot discharge the residual charges, and the state in which the processing-target substrate 100 is electrostatically attracted to the stage 200 is not released. Therefore, damage 204 such as cracks occurs in the semiconductor substrate 101 of the processing-target substrate 100. In a case where the processing-target substrate 100 does not include the dielectric layer 102, the charges 202 stored in the conductive layer 103 leak to the stage 200 through the semiconductor substrate 101 even after the conductive layer 103 is processed into a pattern shape by dry etching. Therefore, the problem of dechucking failure does not occur.

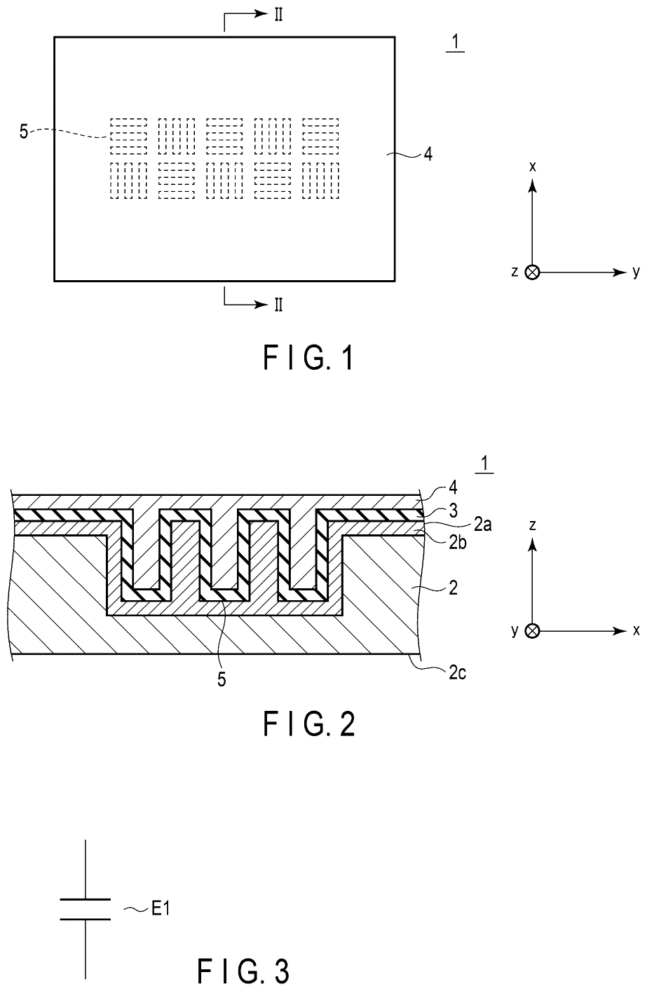

A method of manufacturing a capacitor according to an embodiment will be described with reference to FIGS. 1 to 29. In each drawing, the z-axis direction is a direction parallel to a thickness direction of the semiconductor substrate, the x-axis direction is a direction parallel to the main surface of the semiconductor substrate, and the y-axis direction is a direction parallel to the main surface of the semiconductor substrate and perpendicular to the x-axis direction.

### (First Step)

The first step includes providing a dielectric layer and a first conductive layer on a semiconductor substrate having one or more recesses in one main surface. Hereinafter, the first step will be described with reference to FIGS. 1 to 3. FIG. 1 is a top view of a substrate to be processed. The substrate to be processed may be named the processing-target substrate. FIG. 2 shows a cross-sectional view of the processing-target substrate shown in FIG. 1 taken along line II-II. FIG. 3 is a schematic circuit diagram illustrating a connection state of a portion to be a first fuse portion (poly-si fuse portion).

A processing-target substrate 1 includes a semiconductor substrate 2, a dielectric layer 3, and a first conductive layer 4.

The semiconductor is, for example, silicon (Si); germanium (Ge); a semiconductor formed of a compound of a group III element and a group V element, such as gallium arsenide (GaAs) or gallium nitride (GaN); and silicon carbide (SiC). The term “group” used herein is a “group” in the short-form periodic table.

The semiconductor substrate is, for example, a semiconductor wafer. The semiconductor wafer may be doped with an impurity, and may include a semiconductor element such as a transistor or a diode. Further, a main surface of the semiconductor wafer may be parallel to any crystal plane of the semiconductor. A usable semiconductor wafer is, for example, a Si wafer (silicon wafer) whose main surface is a (100) plane or a Si wafer (silicon wafer) whose main surface is a (110) plane.

The semiconductor substrate 2 exemplified in FIG. 2 is a Si wafer having a doped layer 2b doped with P-type or N-type impurities on one main surface 2a. A plurality of recesses (trenches) 5 are provided in one main surface 2a of the semiconductor substrate 2. The recesses (trenches) 5 can be processed by, for example, metal-assisted chemical etching (MacEtch). A depth direction of each recess (trench) 5 is along the z-axis direction. Among the recesses 5, some recesses 5 are arranged along the x-axis direction at intervals from each other, and other recesses 5 are arranged along the y-axis direction at intervals from each other. A pattern in which the recesses 5 are arranged along the x-axis direction and a pattern in which the recesses are arranged along the y-axis direction are alternately disposed along each of the x-axis direction and the y-axis direction. FIG. 2 illustrates a pattern in which the recesses 5 are arranged along the x-axis direction, and does not illustrate a pattern in which the recesses are arranged along the y-axis direction.

The dielectric layer 3 is provided on the main surface 2a of the semiconductor substrate 2 and an inner surface of each recess 5. The dielectric layer is made of, for example, an organic dielectric or an inorganic dielectric. As the organic dielectric, for example, polyimide can be used. As the inorganic dielectric, a ferroelectric can also be used, and examples of the inorganic dielectric layer can include an oxide film and a nitride film. Paraelectrics such as silicon nitride, silicon oxide, silicon oxynitride, titanium oxide, and tantalum oxide are preferable. These paraelectrics have a small change in dielectric constant due to temperature. Therefore, the dielectric layer including the paraelectric can enhance heat resistance of the capacitor.

The first conductive layer 4 is embedded in each recess 5. The first conductive layer 4 is in contact with the dielectric layer 3 in the recess 5. The first conductive layer 4 covers the dielectric layer 3 located on the main surface 2a of the semiconductor substrate 2. The first conductive layer 4 embedded in each recess 5 is connected to the first conductive layer 4 disposed above the main surface 2a of the semiconductor substrate 2. The first conductive layer 4 is disposed on the dielectric layer 3 located on the main surface 2a of the semiconductor substrate 2. Therefore, the first conductive layers 4 embedded in the respective recesses 5 are electrically connected to each other. The first conductive layer 4 is formed of, for example, poly-Si (poly-silicon) doped with impurities. The poly-Si doped with impurities has low resistance. Examples of the impurities can include P-type impurities and N-type impurities. The first conductive layer 4 is not limited to poly-Si, and may be formed of, for example, a metal such as molybdenum, aluminum, gold, tungsten, platinum, nickel, or copper, or an alloy including the metal. The first conductive layer 4 may have a single-layer structure or a multilayer structure.

The dielectric layer 3 and the first conductive layer 4 may be formed not only on the main surface 2a of the semiconductor substrate 2 but also on the other main surface 2c and an end surface connecting the main surfaces 2a and 2c.

A fuse portion is not yet provided on the processing-target substrate 1. Therefore, as illustrated in FIG. 3, a portion to be a fuse portion is in a state E1 in which a capacitor having a metal-insulator-metal (MIM) structure is formed by the first conductive layer 4, the dielectric layer 3, and the semiconductor substrate 2.

### (Second Step)

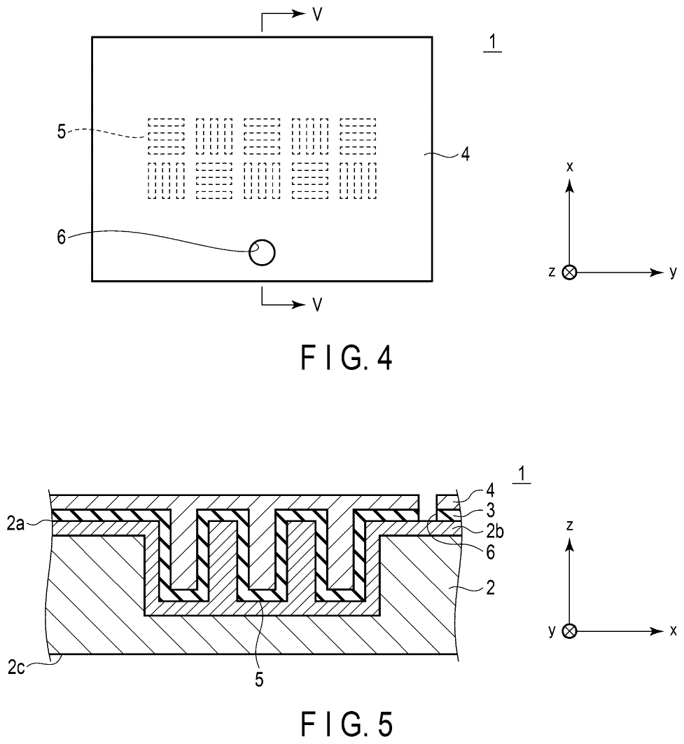

The second step includes providing one or more openings in the dielectric layer and the first conductive layer located on the main surface of the semiconductor substrate. Hereinafter, the second step will be described with reference to FIGS. 4 to 5. FIG. 4 is a top view of a processing-target substrate. FIG. 5 is a cross-sectional view of the processing-target substrate illustrated in FIG. 4 taken along line V-V.

One or more openings 6 penetrating the dielectric layer 3 and the first conductive layer 4 located on the main surface 2a of the semiconductor substrate 2 are provided therein. The opening 6 is desirably provided at a portion away from a region where the pattern of the recesses 5 is formed. In the example illustrated in FIG. 4, the opening 6 is provided near a center of a side portion parallel to the y-axis direction of the main surface 2a of the semiconductor substrate 2. The opening 6 is a cylindrical cavity having a part of the dielectric layer 3 and a part of the first conductive layer 4 as inner walls and a part of the main surface 2a of the semiconductor substrate 2 as a bottom wall. The opening 6 is defined by the part of the dielectric layer 3, the part of the first conductive layer 4 and the part of the main surface 2a of the semiconductor substrate 2. The opening 6 constitutes the first fuse portion, but the first fuse portion has not yet been completed at a stage where the second step is completed. Therefore, the portion to be the first fuse portion is in a state E1 in which the capacitor having the MIM structure similar to that in the first step is formed.

In FIGS. 4 and 5, the number of the opening 6 is one, but is not limited thereto, and a plurality of openings may be provided.

The opening 6 can be processed by dry etching such as chemical dry etching (CDE). As an example of CDE, reactive ion etching (RIE) is indicated.

The dry etching is performed in a state where the processing-target substrate 1 is held by an electrostatic chuck (ESC chuck). The first conductive layer 4 is formed of, for example, poly-Si doped with impurities, and thus can store charges from the electrostatic chuck. As a result, the semiconductor substrate 2 of the processing-target substrate 1 is electrostatically attracted to a stage of the electrostatic chuck. Although not illustrated, the first conductive layer 4 is provided not only on the main surface 2a of the semiconductor substrate 2 but also on the other main surface 2c and an end surface connecting the main surfaces 2a and 2c. As a result, the first conductive layer 4 is electrically conducted with the stage of the electrostatic chuck. In a case where the processing-target substrate 1 is detached from the electrostatic chuck by pushing up the processing-target substrate by the conductive lift pin after the dry etching process, residual charges in the first conductive layer 4 can be escaped from the first conductive layer 4 to the stage, and thus the processing-target substrate 1 can be detached from the electrostatic chuck without being damaged.

### (Third Step)

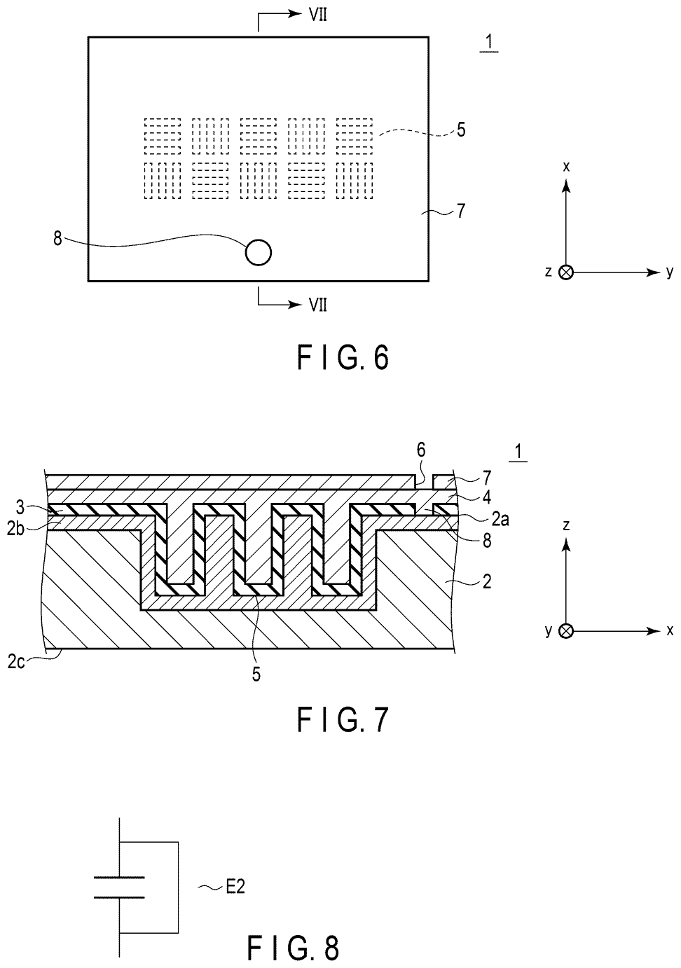

The third step includes providing a first conductive material portion in the opening. The first conductive material portion constitutes a first fuse portion (for example, a poly-Si fuse portion). Hereinafter, the third step will be described with reference to FIGS. 6 to 8. FIG. 6 is a top view of a processing-target substrate. FIG. 7 is a cross-sectional view of the processing-target substrate illustrated in FIG. 6 taken along line VII-VII. FIG. 8 is a schematic circuit diagram illustrating a connection state of the first fuse portion (poly-Si fuse portion).

A second conductive layer 7 is provided on the first conductive layer 4 located on the entire surface of the main surface 2a of the semiconductor substrate 2 of the processing-target substrate 1. At this time, a first conductive material portion 8 made of the same material as that for the second conductive layer 7 is embedded in the opening 6. The first conductive material portion 8 is in direct contact with the main surface 2a of the semiconductor substrate 2 located in the opening 6. The first conductive material portion 8 is also in contact with the first conductive layer 4. Therefore, the first conductive layer 4 is electrically conducted with the semiconductor substrate 2 via the first conductive material portion 8. The first conductive material portion 8 is also referred to as first fuse portion (poly-Si fuse portion). As illustrated in FIG. 8, the electrical connection state in the first fuse portion (poly-Si fuse portion) has a state E2 in which the first conductive layer 4 is directly electrically connected to the semiconductor substrate 2.

The second conductive layer 7 can be formed of, for example, the same material as that for the first conductive layer 4. FIG. 7 illustrates a boundary between the first conductive layer 4 and the second conductive layer 7 for easy understanding, but the boundary (interface) between the first conductive layer 4 and the second conductive layer 7 is not clear in some cases.

### (Fourth Step)

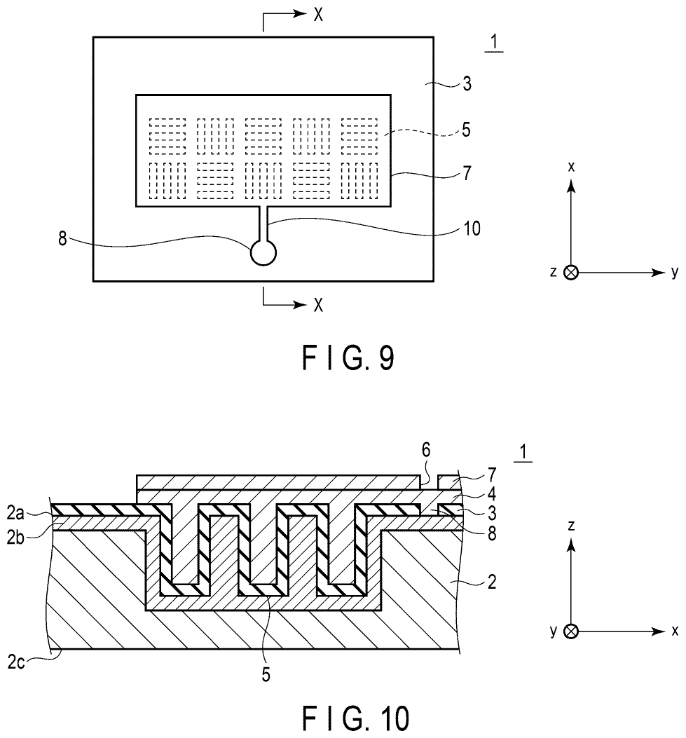

The fourth step includes patterning the first conductive layer and the second conductive layer by dry etching. Hereinafter, the fourth step will be described with reference to FIGS. 9 to 10. FIG. 9 is a top view of a processing-target substrate. FIG. 10 is a cross-sectional view of the processing-target substrate illustrated in FIG. 9 taken along line X-X.

The first conductive layer 4 and the second conductive layer 7 of the processing-target substrate 1 are processed into a pattern shape using dry etching. Dry etching may be performed after formation of a mask by photolithography. The patterning is performed to partition the first conductive layer 4 and the second conductive layer 7 for each chip, thereby obtaining the first conductive layer 4 and the second conductive layer 7 each having a target area for one chip. However, if the first conductive layer 4 and the second conductive layer 7 are processed to have a target area, electrical conduction between the first conductive layer 4 and a first fuse portion 8 is disconnected. Therefore, patterning is performed such that a connection portion (wiring portion) 10 that electrically conducts the first conductive layer 4 and the first fuse portion 8 is provided. Specifically, the first conductive layer 4 and the second conductive layer 7 located outside the region where the pattern of the recesses 5 is formed, in other words, at an edge portion of the main surface 2a of the semiconductor substrate 2 are removed by dry etching except for a portion to be the connection portion 10. The connection portion 10 formed by directly extending from each of the first conductive layer 4 and the second conductive layer 7 is connected to the opening 6. Therefore, the connection portion 10 is located on the inner wall of the opening 6. The first fuse portion 8 embedded in the opening 6 is in contact with the connection portion 10 located on the inner wall of opening 6. The first fuse portion 8 is also in contact with the main surface 2a of the semiconductor substrate 2 located on the bottom wall of the opening 6. As a result, the first conductive layer 4 and the second conductive layer 7 are electrically connected to the semiconductor substrate 2 by the connection portion 10 and the first fuse portion 8. The electrical connection state in the first fuse portion (poly-Si fuse portion) 8 is a state E2 similar to that in the third step.

Examples of the dry etching can include the same types as those described for the third step.

The dry etching is performed in a state where the processing-target substrate 1 is held by an electrostatic chuck (ESC chuck). In a case where the processing-target substrate 1 is detached from the electrostatic chuck by pushing up the processing-target substrate by the conductive lift pin after the dry etching process, residual charges in the first conductive layer 4 and the second conductive layer 7 can flow from the first fuse portion 8 to the semiconductor substrate 2 and be escaped from the semiconductor substrate 2 to the stage, and thus the processing-target substrate 1 can be detached from the electrostatic chuck without being damaged.

### (Fifth Step)

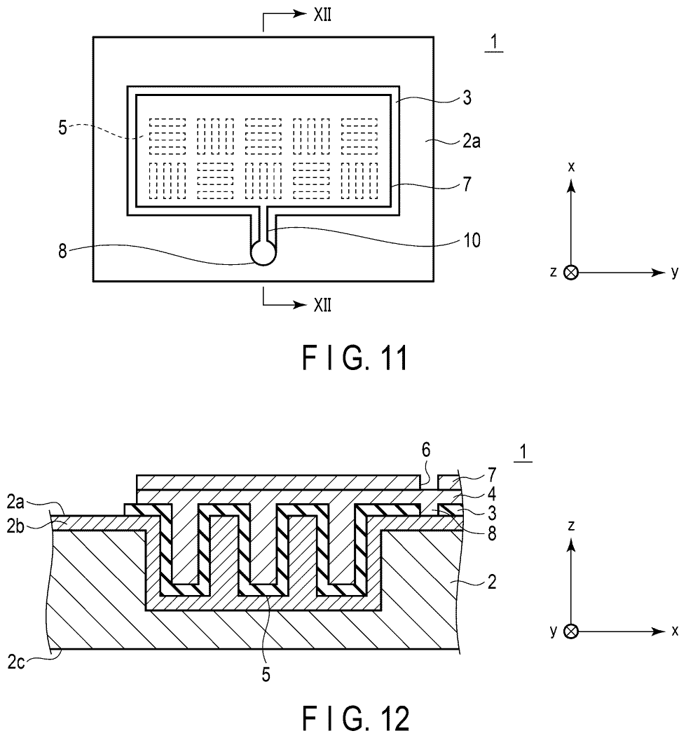

The fifth step includes patterning the dielectric layer 3 by dry etching. Hereinafter, the fifth step will be described with reference to FIGS. 11 to 12. FIG. 11 is a top view of a processing-target substrate. FIG. 12 is a cross-sectional view of the processing-target substrate illustrated in FIG. 11 taken along line XII-XII.

The dielectric layer 3 of the processing-target substrate 1 is processed into a pattern shape by dry etching. Dry etching may be performed after formation of a mask by photolithography. The patterning is performed to partition the dielectric layer 3 formed on the entire main surface 2a of the semiconductor substrate 2 for each chip, thereby obtaining the dielectric layer 3 having a target area for one chip. The electrical connection state in the first fuse portion 8 (poly-Si fuse portion) is a state E2 similar to that in the third step.

Examples of the dry etching can include the same types as those described for the third step.

The dry etching is performed in a state where the processing-target substrate 1 is held by an electrostatic chuck (ESC chuck). In a case where the processing-target substrate 1 is detached from the electrostatic chuck by pushing up the processing-target substrate by the conductive lift pin after the dry etching process, residual charges in the first conductive layer 4 and the second conductive layer 7 can flow from the first fuse portion 8 to the semiconductor substrate 2 and be escaped from the semiconductor substrate 2 to the stage, and thus the processing-target substrate 1 can be detached from the electrostatic chuck without being damaged.

### (Sixth Step)

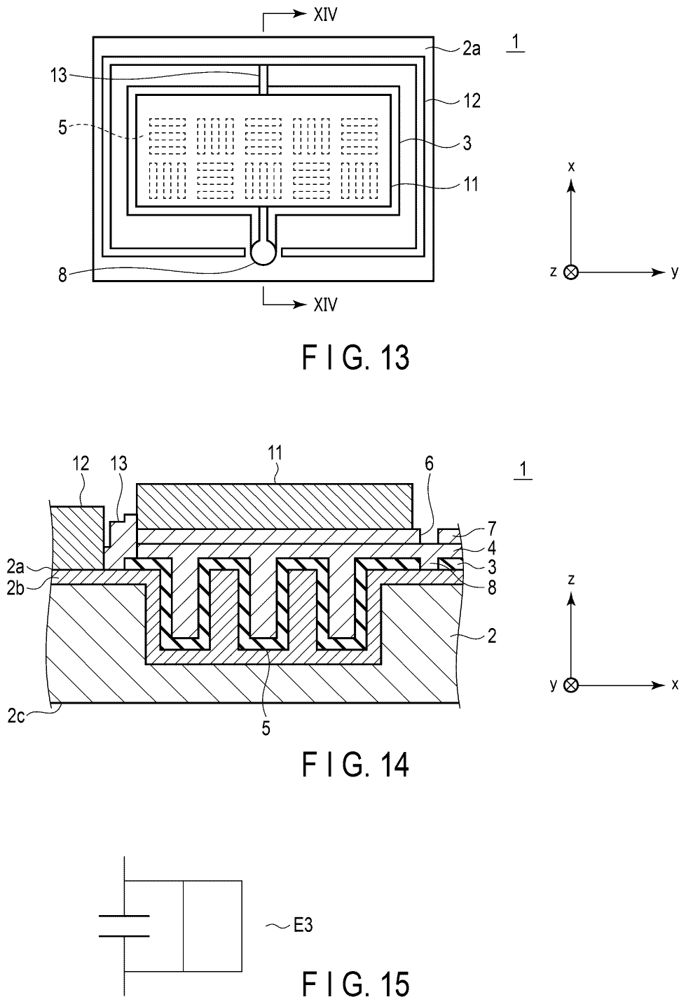

The sixth step includes providing a first contact electrode on the conductive layer, providing a second contact electrode on the semiconductor substrate, and providing a second conductive material portion electrically connecting the first contact electrode and the second contact electrode. The formation of the first contact electrode, the formation of the second contact electrode, and the formation of the second conductive material portion may be performed in this order, or the second conductive material portion may be formed after the formation of the first contact electrode and the second contact electrode, or all of them may be performed in a batch. Hereinafter, the sixth step will be described with reference to FIGS. 13 to 15. FIG. 13 is a top view of a processing-target substrate. FIG. 14 is a cross-sectional view of the processing-target substrate illustrated in FIG. 13 taken along line XIV-XIV. FIG. 15 is a schematic circuit diagram illustrating a connection state of the first fuse portion (poly-Si fuse portion).

The conductive layer includes the first conductive layer 4 and the second conductive layer 7. A first contact electrode 11 is provided on an xy plane of the second conductive layer 7. On the other hand, a second contact electrode 12 is provided on the main surface 2a of the semiconductor substrate 2. The second conductive material portion 13 is disposed, for example, between the first contact electrode 11 and the second contact electrode 12 at a position facing the first fuse portion 8 with the first contact electrode 11 interposed between the second conductive material portion 13 and the first fuse portion 8. The second conductive material portion 13 is in contact with both the first contact electrode 11 and the second contact electrode 12. The second conductive material portion 13 electrically connects the first contact electrode 11 and the second contact electrode 12. Thus, the first contact electrode 11 and the second contact electrode 12 are short-circuited by the second conductive material portion 13. Therefore, the second conductive material portion 13 acts as a second fuse portion (Al fuse portion) that brings the conductive layer into electrical conduction with the semiconductor substrate 2. Therefore, as illustrated in FIG. 15, there is established a state E3 in which the conductive layer is electrically conducted with the semiconductor substrate 2 by each of the first fuse portion 8 and the second fuse portion 13.

Each of the first contact electrode 11, the second contact electrode 12, and the second conductive material portion 13 is formed of, for example, a metal such as aluminum. Each of the first contact electrode 11, the second contact electrode 12, and the second conductive material portion 13 is obtained by forming a film by sputtering, for example. The sputtering can provide the first contact electrode 11, the second contact electrode 12, and the second conductive material portion 13 in a batch, and thus the number of steps required for manufacturing can be reduced.

Before the Al sputtering, a barrier layer may be provided on the second conductive layer 7 and the semiconductor substrate 2. The barrier layer can be formed of, for example, Ti or TiN. The barrier layer can be formed by sputtering, for example.

### (Seventh Step)

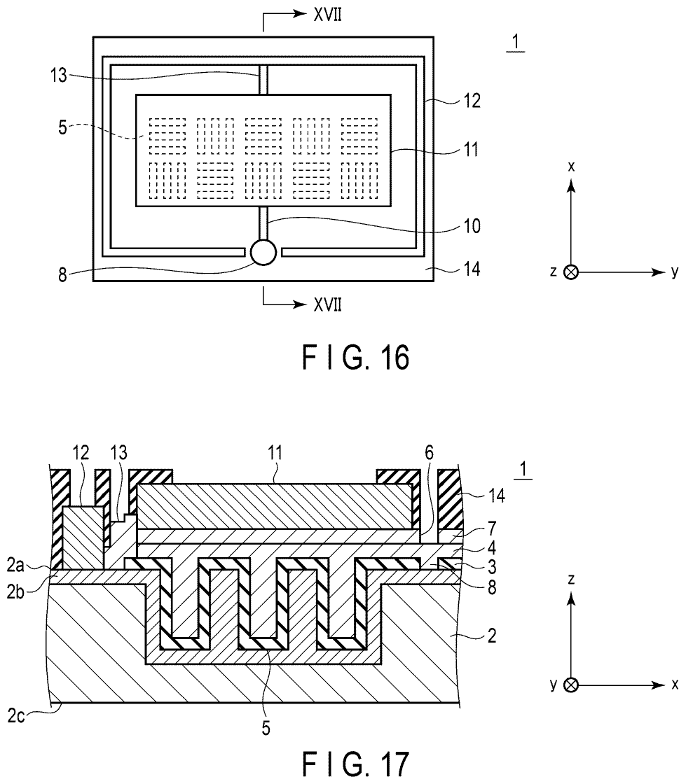

The seventh step includes forming an insulating layer (first insulating layer). Hereinafter, the seventh step will be described with reference to FIGS. 16 to 17. FIG. 16 is a top view of a processing-target substrate. FIG. 17 is a cross-sectional view of the processing-target substrate illustrated in FIG. 16 taken along line XVII-XVII.

For insulation of each of the first contact electrode 11, the second contact electrode 12, the first fuse portion 8, and the second fuse portion 13, a first insulating layer 14 is provided at a target position of the processing-target substrate 1. The first insulating layer 14 is also referred to as interlayer insulating film. The first insulating layer 14 is formed of an insulating material such as tetraethoxysilane (TEOS) or polyethylenimine (PI).

The states of the first fuse portion 8 and the second fuse portion 13 are a state E3 similar to that in the sixth step.

### (Eighth Step)

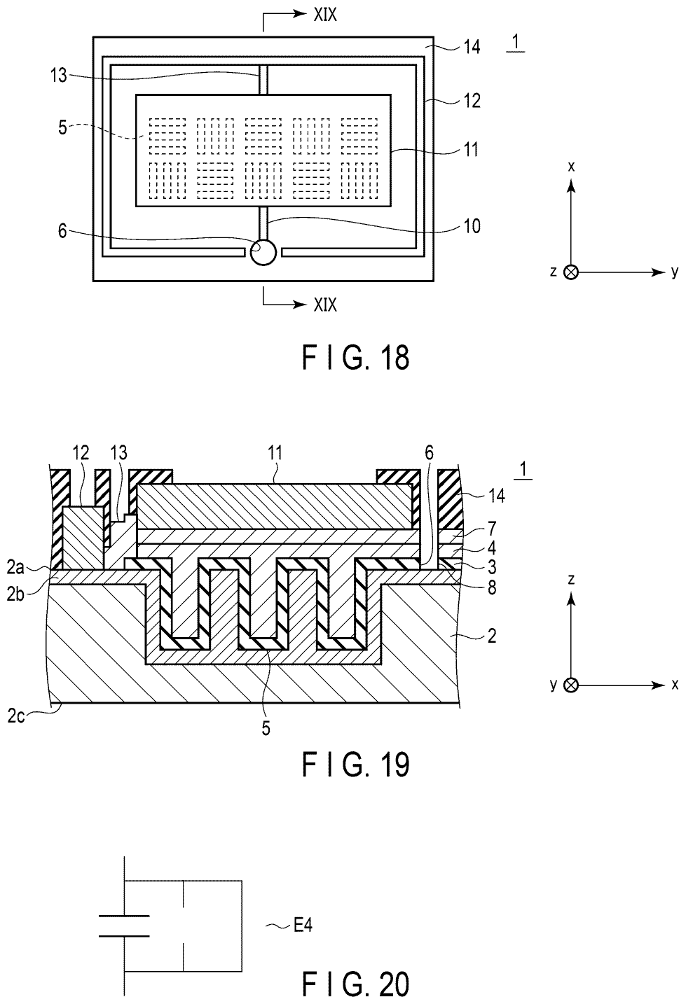

The eighth step includes removing first fuse portion 8 by dry etching. Hereinafter, the eighth step will be described with reference to FIGS. 18 to 20. FIG. 18 is a top view of a processing-target substrate. FIG. 19 is a cross-sectional view of the processing-target substrate illustrated in FIG. 18 taken along line XIX-XIX. FIG. 20 is a schematic circuit diagram illustrating a connection state of the first fuse portion (poly-Si fuse portion) and the second fuse portion (Al fuse portion).

The first fuse portion 8 embedded in the opening 6 is removed by dry etching. Dry etching may be performed after formation of a mask by photolithography. As a result, electrical conduction (state E2) between the conductive layer (in this case, including the first conductive layer 4 and the second conductive layer 7) and the semiconductor substrate 2 is disconnected. The disconnected state is indicated by reference numeral E4 in FIG. 20.

Examples of the dry etching can include the same types as those described for the third step.

The dry etching is performed in a state where the processing-target substrate 1 is held by an electrostatic chuck (ESC chuck). Although electrical conduction through the first fuse portion 8 is disconnected by dry etching, electrical conduction (state E3) between the conductive layer and the semiconductor substrate 2 can be secured by the second fuse portion 13. In a case where the processing-target substrate 1 is detached from the electrostatic chuck by pushing up the processing-target substrate by the conductive lift pin, residual charges in the conductive layer can flow from the second fuse portion 13 to the semiconductor substrate 2 and be escaped from the semiconductor substrate 2 to the stage, and thus the processing-target substrate 1 can be detached from the electrostatic chuck without being damaged.

### (Ninth Step)

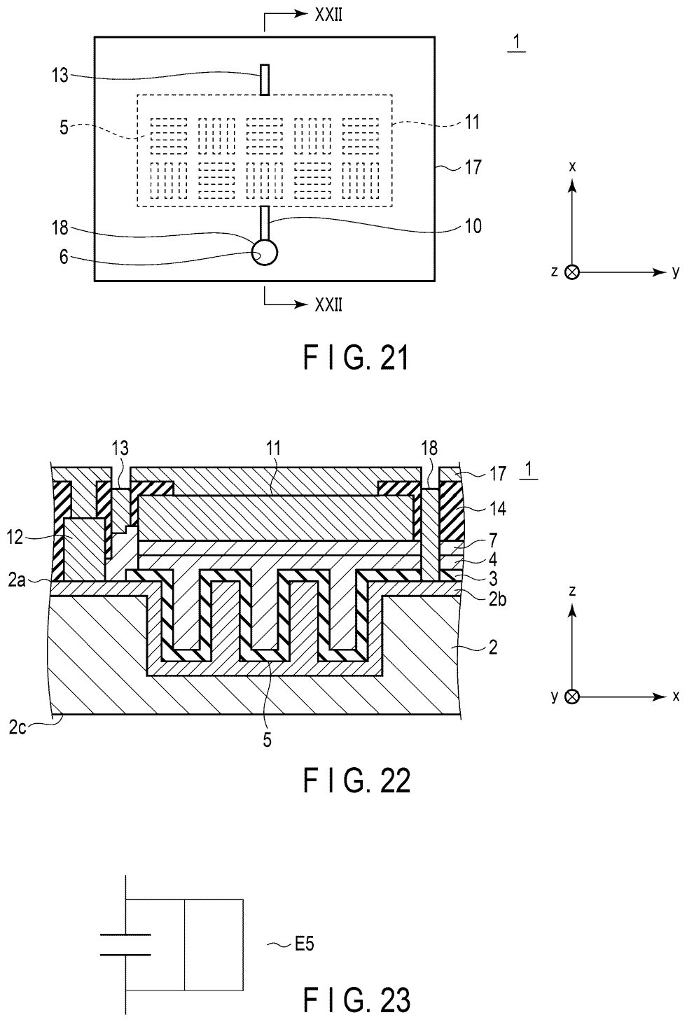

The ninth step includes providing a first pad electrode on the first contact electrode and providing a second pad electrode on the second contact electrode. The formation of the first pad electrode and the formation of the second pad electrode may be performed in this order, the order may be reversed, or the first pad electrode and the second pad electrode may be formed in a batch. Hereinafter, the ninth step will be described with reference to FIGS. 21 to 23. FIG. 21 is a top view of a processing-target substrate. FIG. 22 is a cross-sectional view of the processing-target substrate illustrated in FIG. 21 taken along line XXII-XXII. FIG. 23 is a schematic circuit diagram illustrating a connection state of the second fuse portion (Al fuse portion) and a third fuse portion (Al fuse portion).

The electrode layer 17 to be the first pad electrode 15 and the second pad electrode 16 is provided on an xy plane including the first contact electrode 11 and the second contact electrode 12. A third conductive material portion 18 may be embedded in the opening 6. The third conductive material portion 18 is in contact with the main surface 2a of the semiconductor substrate 2 located in the opening 6 and is in contact with the connection portion 10 located on the inner wall of the opening 6. Therefore, the third conductive material portion 18 electrically connects the conductive layer constituting the connection portion 10 and the semiconductor substrate 2, and thus functions as a third fuse portion 18.

Therefore, the processing-target substrate 1 has an electrical conduction state E5 by the second fuse portion 13 and the third fuse portion 18.

Each of the electrode layer 17 (including the first pad electrode 15 and the second pad electrode 16) and the third fuse portion 18 is made of metal such as aluminum. Each of the electrode layer 17 and the third fuse portion 18 is obtained by forming a film by sputtering, for example.

### (Tenth Step)

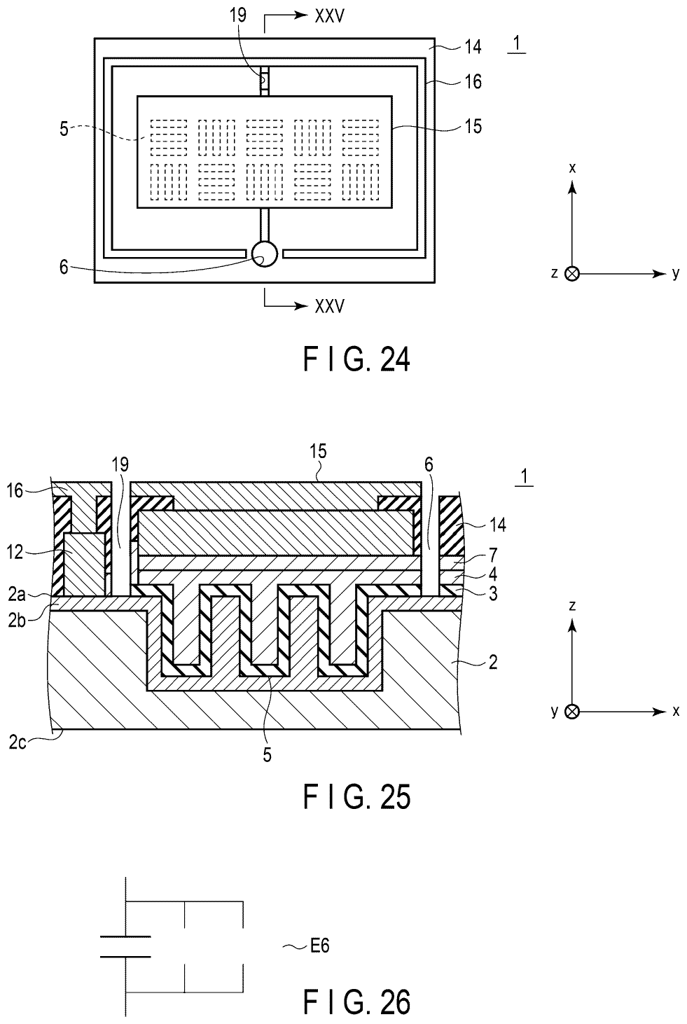

The tenth step includes patterning the electrode layer into a target shape by wet etching. Hereinafter, the tenth step will be described with reference to FIGS. 24 to 26. FIG. 24 is a top view of a processing-target substrate. FIG. 25 is a cross-sectional view of the processing-target substrate illustrated in FIG. 24 taken along line XXV-XXV. FIG. 26 is a schematic circuit diagram illustrating a connection state of the second fuse portion (Al fuse portion) and the third fuse portion

### (Al Fuse Portion).

The electrode layer 17 is patterned into a target shape by wet etching. Wet etching may be performed after formation of a mask by photolithography. Consequently, the first pad electrode 15 and the second pad electrode 16 are separated from each other. The first pad electrode 15 is electrically connected to the first contact electrode 11 in contact with an xy plane of the first contact electrode 11. The second pad electrode 16 is electrically connected to the second contact electrode 12 in contact with an xy plane of the second contact electrode 12. The second fuse portion 13 and the third fuse portion 18 embedded in the opening 6 are removed by wet etching. After removal of the second fuse portion 13, a hole 19 including a part of the main surface 2a of the semiconductor substrate 2 as a bottom wall is formed between the first contact electrode 11 and the second contact electrode 12. The bottom wall of the hole 19 is defined by the part of the main surface 2a of the semiconductor substrate 2. As a result, electrical conduction between the first contact electrode 11 and the second contact electrode 12 and electrical conduction between the semiconductor substrate 2 located in the opening 6 and the connection portion 10 are disconnected. Therefore, as illustrated in FIG. 26, the processing-target substrate 1 has a state E6 in which electrical conduction by the second fuse portion 13 and electrical conduction by the third fuse portion 18 are disconnected.

Examples of a wet etching agent can include an aqueous solution containing HF and an aqueous solution containing a mixed acid (for example, containing acetic acid, phosphoric acid, and nitric acid). In a case where the first pad electrode 15, the second pad electrode 16, and the third conductive material portion 18 are formed of aluminum, an aqueous solution containing a mixed acid can be used as the wet etching agent. In a case where the barrier layer is provided, an aqueous solution containing HF can be used as the wet etching agent.

For easy understanding, FIG. 25 illustrates that there is a boundary between the first contact electrode 11 and the first pad electrode 15 and between the second contact electrode 12 and the second pad electrode 16, but there is not necessarily a boundary (interface).

### (Eleventh Step)

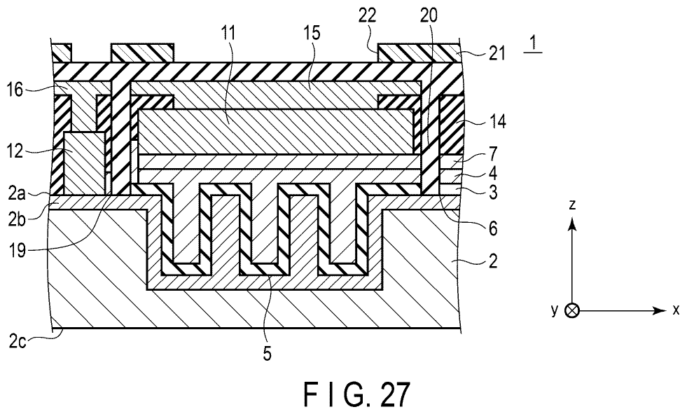

The eleventh step includes providing an insulating layer (second insulating layer) and providing a mask layer. Hereinafter, the eleventh step will be described with reference to FIG. 27. FIG. 27 is a cross-sectional view of the processing-target substrate taken along the x-axis direction.

The entire upper surface of the processing-target substrate 1 along the xy plane is covered with a second insulating layer 20. Therefore, the second insulating layer 20 is embedded in the hole 19 provided after removal of the second fuse portion 13 and the opening 6 from which the third fuse portion 18 is removed. The connection portion 10 is also covered with the second insulating layer 20. The second insulating layer 20 is formed of an insulating material such as tetraethoxysilane (TEOS) or polyethylenimine (PI).

A mask layer 21 is provided on the second insulating layer 20. The mask layer 21 has a pattern shape having an opening 22. The pattern shape is not particularly limited as long as it has a target shape, and, for example, can be provided such that the first pad electrode 15 and the second pad electrode 16 are located on the upper surface along the xy plane of the capacitor. The mask layer 21 can be formed of, for example, an organic material such as polyimide, fluororesin, phenol resin, acrylic resin, or novolak resin, or an inorganic material such as silicon oxide or silicon nitride. The mask layer 21 may be formed by, for example, an existing semiconductor process.

For easy understanding, FIG. 27 illustrates that there is a boundary between the first insulating layer 14 and the second insulating layer 20, but there is not necessarily a boundary (interface).

### (Twelfth Step)

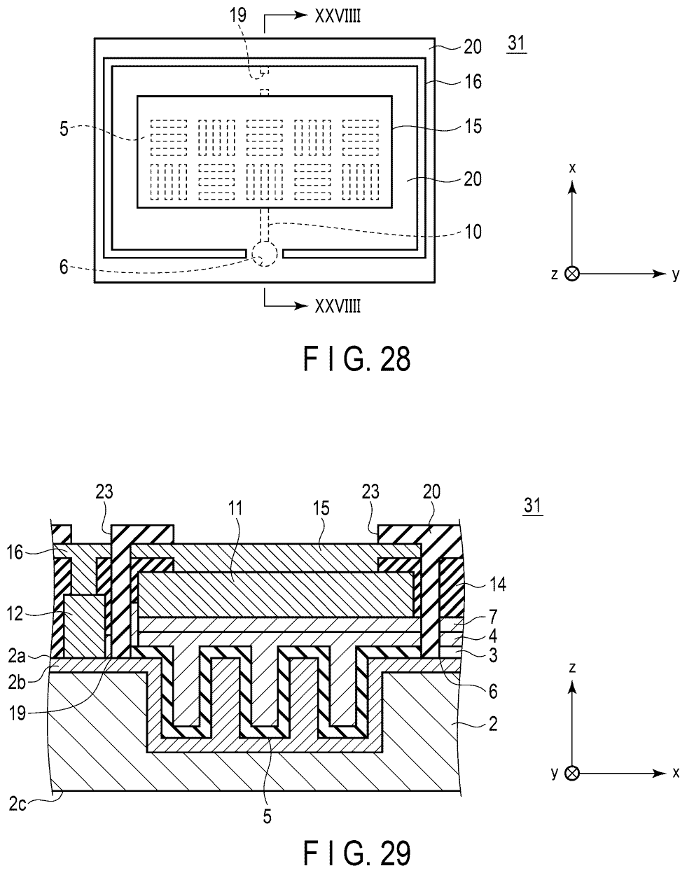

The twelfth step includes patterning the second insulating layer into a target shape. Hereinafter, the twelfth step will be described with reference to FIGS. 28 to 29. FIG. 28 is a top view of a capacitor. FIG. 29 is a cross-sectional view of the capacitor illustrated in FIG. 28 taken along line XXVIIII-XXVIIII.

The second insulating layer 20 is patterned into a target shape. The patterning can be performed by, for example, wet etching, patterning by exposure and development, or the like. As a result of the patterning, as illustrated in FIG. 29, the first pad electrode 15 and the second pad electrode 16 are located in an opening 23 of the second insulating layer 20 on the upper surface along the xy plane of a capacitor 31. The first pad electrode 15 and the second pad electrode 16 are electrically insulated by the second insulating layer 20 interposed therebetween. The second insulating layer 20 also surrounds an outer wall of second pad electrode 16.

For easy understanding, FIG. 29 illustrates that there is a boundary between the first insulating layer 14 and the second insulating layer 20, but there is not necessarily a boundary (interface).

The capacitor 31 illustrated in FIGS. 28 and 29 is obtained by the method including the above first to twelfth steps. The capacitor 31 illustrated in FIGS. 28 and 29 includes a semiconductor substrate 2 including a main surface 2a having one or more recesses 5, conductive layers 4 and 7 provided in each recess 5 and on the main surface 2a of the semiconductor substrate, a dielectric layer 3 disposed between the conductive layers 4 and 7 and the semiconductor substrate 2, a connection portion 10 directly extending from one or more portions of the conductive layers 4 and 7, and an opening 6 connected to the connection portion 10 and including a bottom wall located in the main surface 2a of the semiconductor substrate 2. The capacitor 31 has a hole 19 formed by removing the second fuse portion 13. An insulating layer 20 (insulating material) may be embedded in the opening 6 and the hole 19.

An operation of detaching the processing-target substrate 1 from an electrostatic chuck after processing the pattern shape in the conductive layer by reactive ion etching in a state where the processing-target substrate 1 on which the first fuse portion 8 was formed was clamped on the electrostatic chuck was repeated 10 times. The processing-target substrate 1 could be detached from the electrostatic chuck without causing damage, such as cracks, to the processing-target substrate 1 in all the times. In addition, an operation of detaching the processing-target substrate 1 from an electrostatic chucks after removing the first fuse portion 8 by reactive ion etching was repeated 10 times. The processing-target substrate 1 could be detached from the electrostatic chuck without causing damage, such as cracks, to the processing-target substrate 1 in all the times.

Note that the embodiment may include all the first step to the twelfth step, but some steps may be omitted. In addition, other steps such as formation of a mask layer, formation of a barrier layer, and washing may be performed between any of the first step to the twelfth step.

The method and the capacitor of the embodiments can be applied to, for example, a capacitor including a Si wafer having a diameter of 8 inches or more as a semiconductor substrate, examples for such capacitor include a capacitor used in a memory such as a DRAM.

According to the etching method of at least one embodiment described above, after processing the pattern shape in the conductive layer using dry etching, the semiconductor substrate is electrically conducted with the conductive layer by the first conductive material portion and the connection portion. Therefore, after dry etching, the processing-target substrate can be detached from the electrostatic chuck without causing damage, such as cracks, to the processed substrate. In addition, removal of the first conductive material portion by dry etching disconnects the electrical connection between the conductive layer and the semiconductor substrate by the first conductive material portion. Thereafter, since the electrical connection between the conductive layer and the semiconductor substrate is secured by the second conductive material portion, the processing-target substrate can be detached from the electrostatic chuck without causing damage, such as cracks, to the processing-target substrate after removal of the first conductive material portion removed by dry etching. Therefore, the method and the capacitor of the embodiments can reduce damage such as cracks to the processing-target substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a capacitor, the method comprising:
providing a substrate to be processed, the substrate comprising: a semiconductor substrate including a main surface having one or more recesses; a conductive layer provided on the main surface and in the one or more recesses of the semiconductor substrate; and a dielectric layer provided between the conductive layer and the semiconductor substrate, an opening penetrating the dielectric layer and the conductive layer that are located on the main surface of the semiconductor substrate;
providing a first conductive material portion on the main surface of the semiconductor substrate located in the opening;
processing the conductive layer in a pattern shape by dry etching, and the pattern shape including a connection portion extending from the conductive layer and connected to the opening;
providing a first contact electrode electrically connected to the conductive layer, a second contact electrode electrically connected to the semiconductor substrate, and a second conductive material portion electrically connecting the first contact electrode and the second contact electrode;
performing dry etching to the first conductive material portion to disconnect electrical connection between the connection portion and the semiconductor substrate; and
performing wet etching to the second conductive material portion to disconnect electrical connection between the first contact electrode and the second contact electrode.

2. The method of manufacturing a capacitor according to claim 1, wherein the semiconductor substrate is a substrate containing Si, and each of the conductive layer and the first conductive material portion contains poly-Si.

3. The method of manufacturing a capacitor according to claim 1, wherein each of the first contact electrode, the second contact electrode, and the second conductive material portion contains Al.

4. The method of manufacturing a capacitor according to claim 1, wherein the dry etching is performed in a state where the substrate is held by an electrostatic chuck.

5. The method of manufacturing a capacitor according to claim 1, further comprising: after dry etching the first conductive material portion, providing a first pad electrode electrically connected to the first contact electrode, a second pad electrode electrically connected to the second contact electrode, and a third conductive material portion for electrically connecting the main surface of the semiconductor substrate located in the opening and the connection portion.

6. A capacitor comprising:
a semiconductor substrate including a main surface having one or more recesses;
a conductive layer provided in the one or more recesses and on the main surface of the semiconductor substrate;
a dielectric layer disposed between the conductive layer and the semiconductor substrate;
a connection portion from which the conductive layer located on the main surface of the semiconductor substrate extends;
an opening connected to the connection portion and including a bottom wall located in the main surface of the semiconductor substrate;
a first contact electrode electrically connected to the conductive layer;
a second contact electrode electrically connected to the semiconductor substrate;
a hole located between the first contact electrode and the second contact electrode and including a bottom wall located in the main surface of the semiconductor substrate; and
an insulating layer provided in the opening and the hole.
